(19) United States
(12) Patent Application Publication
(10) Pub. No.: US 2024/0313754 A1
(43) Pub. Date: Sep. 19, 2024

(54) MULTISTAGE VOLTAGE COMPARATOR

(71) Applicant: NXP B.V., Eindhoven (NL)

(72) Inventors: Shubham Ajaykumar Khandelwal, Helmond (NL); Gerard Villar Piqué, Eindhoven (NL)

(21) Appl. No.: 18/184,117

(22) Filed: Mar. 15, 2023

(51) Int. Cl. H03K 5/24

(52) U.S. Cl. CPC H03K 5/2481

(57) ABSTRACT

A circuit that includes a voltage comparator for comparing two voltages. The comparator includes a first in series stage with a differential amplifier, a second in series stage with a differential amplifier, and one or more subsequent inverter stages. Each of the stages includes one or more switches for connecting the inputs of the comparison devices of the stages to their outputs during a precharge phase to charge capacitors with voltages based on the voltage thresholds of the comparison devices. In a subsequent comparison phase, the one or more switches are open, where a comparison between the two voltages is propagated through the stages.

### BACKGROUND OF THE INVENTION

### Field of the Invention

This invention relates to a voltage comparator with multiple stages and to circuits implementing such voltage comparators.

### Background

Voltage comparators are utilized in circuits such as switching power supplies for providing an indication of a comparison between two voltages.

### BRIEF DESCRIPTION OF THE DRAWINGS

The present invention may be better understood, and its numerous objects, features, and advantages made apparent to those skilled in the art by referencing the accompanying drawings.

FIG. 1 is a circuit diagram of a prior art switching power supply.

FIG. 2 is a timing diagram of the circuit of FIG. 1.

FIG. 3 is a circuit diagram of a prior art voltage comparator.

FIG. 4 is a timing diagram of the circuits of FIG. 1 and FIG. 3.

FIG. 5 is a circuit of a voltage comparator according to one embodiment of the present invention.

FIG. 6 is a circuit diagram of a switching power supply according to one embodiment of the present invention.

FIG. 7 is a timing diagram of the circuit of FIG. 6 according to one embodiment of the present invention.

FIG. 8 is a circuit diagram of a voltage comparator according to another embodiment of the present invention

The use of the same reference symbols in different drawings indicates identical items unless otherwise noted. The Figures are not necessarily drawn to scale.

### DETAILED DESCRIPTION

The following sets forth a detailed description of a mode for carrying out the invention. The description is intended to be illustrative of the invention and should not be taken to be limiting.

Disclosed herein is a circuit that includes a voltage comparator for comparing two voltages. The comparator includes a first in series stage with a differential amplifier, a second in series stage with a differential amplifier, and one or more subsequent inverter stages. Each of the stages includes one or more switches for connecting the inputs of the comparison devices of the stages to their outputs during a precharge phase to charge capacitors with voltages based on the voltage thresholds of the comparison devices. In a subsequent comparison phase, the one or more switches are open, where a comparison between the two voltages is propagated through the stages.

In one embodiment, providing differential amplifiers for the beginning two or more stages of a voltage comparator may enable the comparator to be more tolerant of supply voltage variations so as to provide for a more accurate comparison of two voltages. Because in some applications the difference in comparison voltages can be minute (e.g., in the hundreds of microvolts range) and variations in the supply voltages may be problematic in single-ended multistage comparators Such a condition may be especially if the supply voltage is different during the pre-charging phase than during the detection phase. Accordingly, utilizing differential amplifiers in the beginning stages enables for a more accurate comparison that is more immune to issues from supply voltage variation.

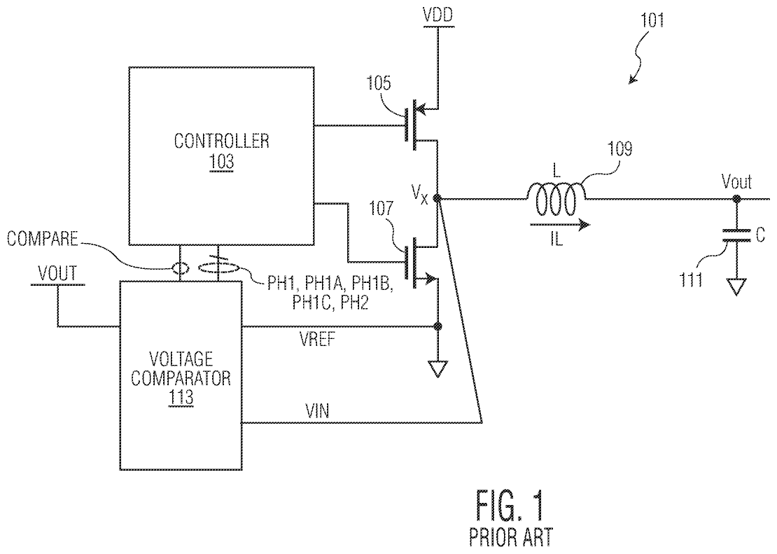

FIG. 1 is a circuit diagram of a DC-DC switching power supply 101 with a buck configuration. Switching power supply 101 includes power switch 105 (implemented with a PFET) and power switch 107 (implemented with an NFET). The conductivity of both power switches is controlled by timing signals from controller 103 to provide a regulated voltage at VOUT. Power supply 101 includes inductor 109 and storage capacitor 111. Power supply 101 also includes a controller 103 and a voltage comparator 113 for comparing the voltage at node VX to ground.

During operation, controller 103 controls the conductivity of power switches 105 and 107 to convert a DC voltage of VDD (e.g., from a battery, rectifier, or USB) to a regulated voltage at VOUT that is at a lower voltage than the voltage of VDD. The voltage at VOUT is dependent on the duty cycle of the PWM signals controlling switches 105 and 107.

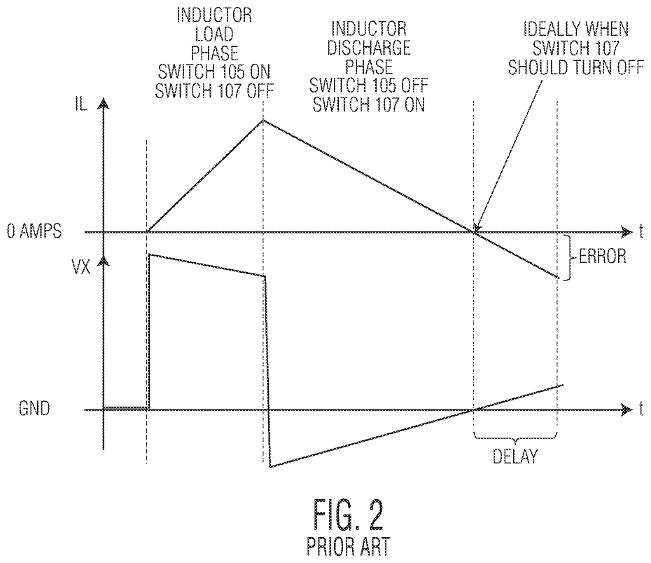

FIG. 2 is a timing diagram of the current of inductor 109 and the voltage of node VX during one cycle of switching power supply 101, when operating in the Discontinuous Conduction Mode (DCM). Each cycle of power supply 101 includes an inductor load phase followed by an inductor discharge phase. In a DCM mode, it may be desirable for switches 105 and 107 to be nonconductive from when the inductor current reaches 0 amps at the end of an inductor discharge phase until the next inductor load phase. In the embodiment of FIGS. 1 and 2, the voltage level of VOUT is controlled by the timing of the control signals provided to switches 105 and 107, where the voltage provided by VOUT is adjusted by changing the timing of the signals. For example, the voltage at VOUT is increased by increasing the percentage of the inductor load phase of the power supply cycle.

Referring to FIG. 2, power supply 101 implements the inductor load phase by making switch 105 conductive and switch 107 nonconductive to load energy into inductor 109 from VDD. During this time, current from VDD flows through conductive switch 105 into inductor 109 and to the output node VOUT. In FIG. 2, IL is the current flowing through inductor 109. Initially when switch 105 is first closed, the voltage of node VX rises towards VDD and the current through inductor 109 is initially at 0 amps. As the voltage of VX remains higher than VOUT, the current through inductor 109 rises and energy storage in the inductor increases. The current through inductor 109 flows to the output node VOUT where it charges capacitor 111 and/or supplies current to a load connected to VOUT (not shown).

After the inductor load phase, switch 105 is turned off and switch 107 is turned on to enter the inductor discharge phase. The voltage at VX being lower than the voltage at VOUT initiates the discharge of inductor to the output node VOUT to supply current to a load (not shown) and to charge capacitor 111. When switch 107 is conductive and inductor 109 is discharging energy, the inductor current flows from ground instead of VDD. Due to the non-zero on-resistance of switch 107, the current of the inductor 109 flowing through switch 107 pulls the voltage of node VX below ground.

Inductor 109 discharges its energy to VOUT until all of its stored energy is gone. At that time, the current through inductor 109 is at 0 amps where the voltage drop across power switch 107 is 0 volts, resulting in the voltages of VX and ground being equal. In an ideal situation when power supply 101 is operating in a Discontinuous Conduction Mode, switch 107 should be turned off when the current through inductor 109 is at 0 amps (indicating that inductor 109 has no remaining stored energy). However, if there is a delay in turning off switch 107, then energy stored in capacitor 111 will begin to be transferred to inductor 109 (as indicated by the negative current for IL in FIG. 2) which is inefficient for power supply operation. Accordingly, if switch 107 stays on too long, power supply 101 losses efficiency which leads to excess battery drainage if VDD is from a battery and/or additional heat generation by supply 101. On the other hand, if switch 107 is turned off earlier than needed, the current flowing through inductor 109 may flow through parasitic devices (e.g., a body diode) or other unwanted path. This may reduce the efficiency of the switching power supply 101 leading to excess battery drainage, or result in potential damage for the circuitry.

Referring back to FIG. 1, supply 101 includes a voltage comparator 113 for comparing the voltage of node VX with ground so as to provide an indication of when current IL is at 0 amps. Based upon this indication, controller 113 makes power switch 107 nonconductive so as to improve power supply efficiency.

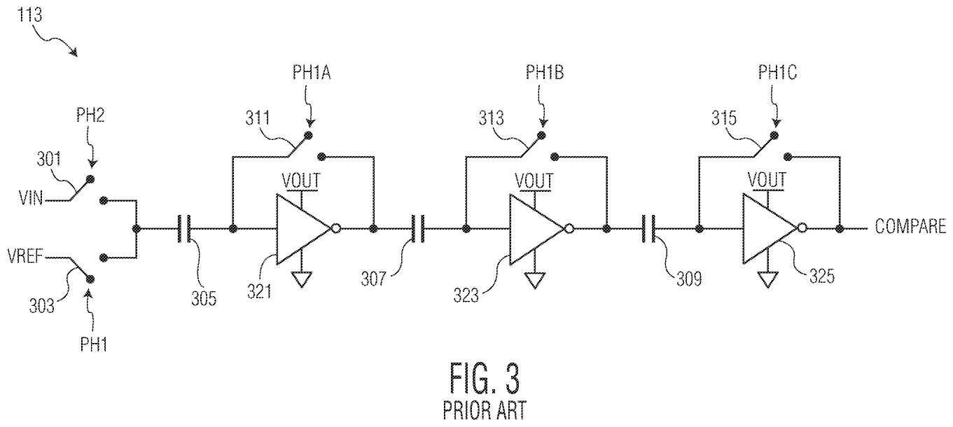

FIG. 3 is a circuit diagram of a prior art comparator 113. As shown in FIG. 3, comparator 113 is multi stage, continuous-time comparator that includes a series of inverters to implement multiple comparator stages. Comparator 113 includes input terminals VIN and VREF, switches 301, 303, 311, 313, and 315, capacitors 305, 307, and 309, and inverters 321, 323, and 325. In FIG. 3, the switches 301, 303, 311, 313, and 315 are closed when the signal to the switch (e.g., PH1, PH2) is asserted and open when the signal is not asserted. Comparator 113 includes an output for providing an indication (COMPARE) of whether VIN is higher than VREF (as indicated by the COMPARE signal being at a low voltage.)

Comparator 113 performs a two-phase comparison operation. In a precharge phase, signals PH1, PH1A, PH1B, and PH1C are asserted and the output of inverters 321, 323, and 325 are shorted to their respective inputs through shorting path switches 311, 313, and 315, respectively to where the output and input of each inverter is at the voltage threshold of the inverter. During Phase 1, switch 303 is closed to provide a path from VREF (ground or other voltage) to capacitor 305. Accordingly, during Phase 1, capacitor 305 is charged with the voltage differential between the voltage threshold of inverter 321 and the voltage of VREF, capacitor 307 is charged with the voltage differential between the voltage threshold of inverter 323 and the voltage threshold of inverter 321, and capacitor 309 is charged with the voltage differential between the voltage threshold of inverter 325 and the voltage threshold of inverter 323.

During Phase 2 (also known as the comparison phase), switches 311, 313, and 315 are opened to make their respective shorting paths nonconductive. Switch 303 is opened and switch 301 is closed to provide a path from VIN via capacitor 305 to the input of inverter 321. Because capacitor 305 is charged to the difference between voltage threshold of inverter 321 and voltage at VREF, the output of inverter 321 will immediately make a decision depending upon whether VIN is higher than VREF (the output of inverter 321 will go low) or VIN is lower than VREF (the output of inverter 321 will go high). In a similar way, the decision of inverter 321, propagates and amplifies relatively quickly through the stages of inverter 323 and inverter 325.

In a situation as shown in FIG. 2 where VX is rising as the energy in inductor drains (as shown by IL falling towards 0 Amps), VIN (the voltage of node VX) is below VREF (where VREF is equal to ground in the example of a DC-DC buck converter of FIG. 1). When VIN just rises above VREF, the output of inverter 321 goes low as capacitor 305 is charge to the voltage threshold of inverter 321. As the comparison propagates through the series of inverters, the output of inverter 321 going low causes the output of inverter 323 to go high which cause the output of inverter 325 (the compare signal) to go low indicating that the current through inductor 109 has reached 0 amps. In response to the COMPARE signal going low, controller 103 turns off switch 107 so that inductor 109 does not discharge capacitor 111, which would lead to a power supply inefficiency.

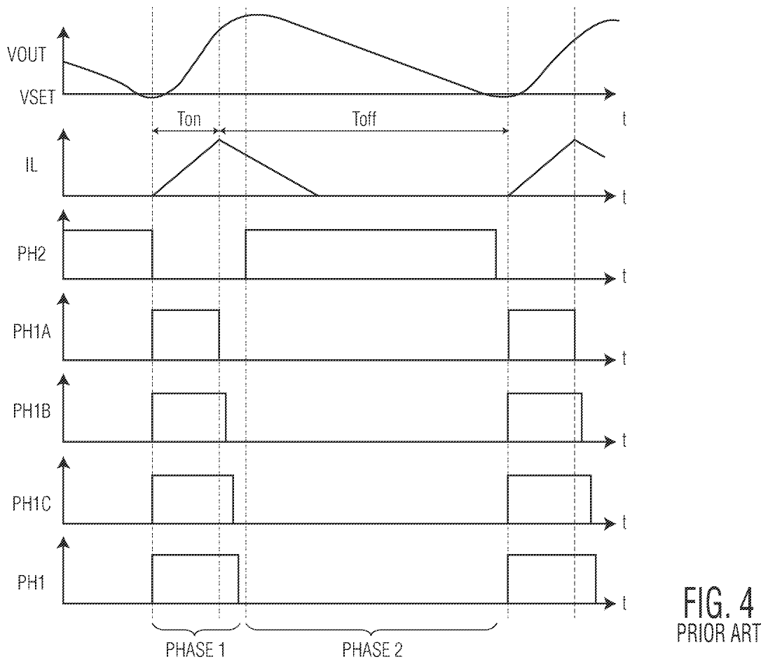

FIG. 4 is a timing diagram of power supply 101 that shows the phase control signals (PH1, PH1A, PH1B, PH1C, and PH2) that are applied to comparator 113 to control the timing of the precharge phase (Phase 1) and the comparison phase (Phase 2). As shown in FIG. 4, TON is the time when switch 105 is conducting and TOFF is the time when switch 105 is nonconducting. In FIG. 4, Phase 1 of comparator 113 (the precharge phase) occurs when the PHASE 1 signal is high. Phase 2 of comparator 113 (the comparison phase) occurs when the PHASE 2 signal is high. In the embodiment of FIG. 4, signals PH1A, PH1B, and PH1C, which are asserted during Phase 1, are deasserted in a staggered manner where PH1A is deasserted before PH1B, PH1B is deasserted before PH1C, and PH1C is deasserted before PH1. The staggered deassertion of these signals reduces the inaccuracy introduced by charge injection that occurs from the opening of the switches.

FIG. 4 shows the voltage of the output (VOUT) of supply 101. In this particular example, VOUT is supplied to the supply rails of inverters 321, 323, and 325. Since a voltage threshold of an inverter is dependent upon its supply rail voltages, the voltage thresholds of inverters 321, 323, and 325 are dependent upon the voltage of VOUT.

As shown in FIG. 4, VOUT is not constant, but instead has a voltage ripple that varies with the timing of the cycles of the switching power supply, which is characteristic of the output of a DC-DC converter. In one example, the variation in the voltage of VOUT may be 15 mV. Accordingly, the voltage thresholds of inverters 321, 323, and 325 will also vary at a fraction of the variance of VOUT.

Because the voltages stored in capacitors 305, 307, and 309 are based on the voltage thresholds of inverters 321, 323, and 325, the voltage thresholds stored in those capacitors during the precharge phase (PHASE 1) may be different from the voltage thresholds of inverters 321, 323, and 325 during the comparison phase when the current through inductor 109 is around 0 Amps. Due to these differences, the input differential signal of the comparator must compensate for the differences in the voltage thresholds stored on the capacitors versus the actual voltage thresholds during the comparison in order to make an accurate decision. However, compensation for voltage threshold differences maybe especially problematic where there is a relatively small voltage differential of the comparator input signals. According, these inaccuracies may cause the comparator output to flip states earlier or later than it should. These inaccuracies especially affect the operation of the first two inverters 321 and 323 of comparator 113 due to the inverters being part of the first and second stages in the series where their input voltages have a relatively low voltage differential. Consequently, such a comparator has a low power supply rejection ratio (PSRR). These inaccuracies due to supply voltage variation can affect the efficiency of switching power supply 101 in that switch 107 may be turned off too early or too late.

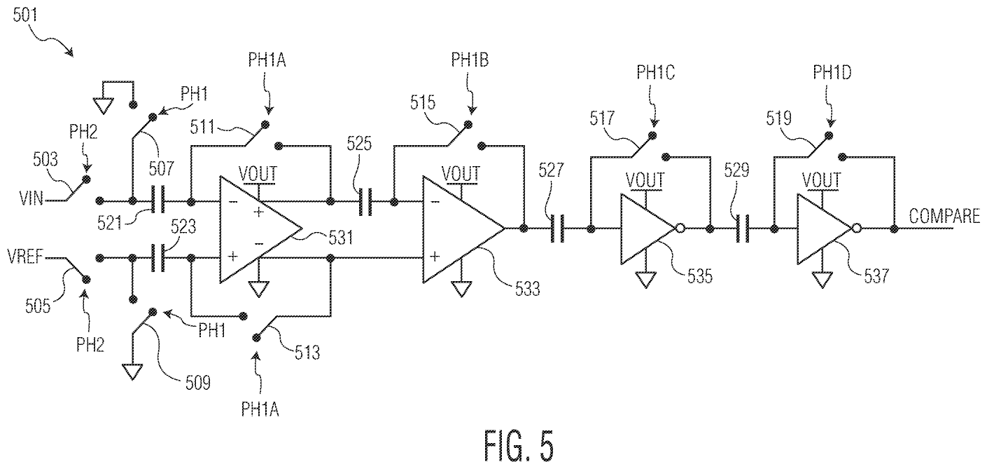

FIG. 5 is a circuit diagram of a comparator according to one embodiment of the present invention. In the embodiment shown, comparator 501 is a multistage, continuous-time, voltage comparator with an improved power supply rejection ratio (PSRR) over the comparator of FIG. 3. Comparator 501 is shown in FIG. 5 as including four stages in series with the first in series stage including a differential amplifier 531, the second in series stage including a differential amplifier 533, the third in series stage including an inverter 535, and the last in series stage including an inverter 537. Comparator 501 includes switches 503, 505, 507, 509, 511, 513, 515, 517, and 519 that are used to implement a precharge phase and a comparison phase. In one embodiment, these switches are implemented with FETs such as NFETs or PFETs, but may be implemented with other types of switches such other types of transistors or passgates.

Comparator 501 also includes capacitors for storing voltage threshold differences between the amplifying devices (e.g., differential amplifiers, inverters) of the stages as determined during the precharge stage. Capacitors 521 and 523 store a voltage differential between the voltage threshold of amplifier 531 and a reference voltage (e.g., ground in FIG. 5 or other reference voltages in other embodiments). Capacitor 525 stores the voltage differential between the voltage threshold of amplifier 533 and the voltage threshold of amplifier 531. Capacitor 527 stores the voltage differential between the voltage threshold of inverter 535 and the voltage threshold of amplifier 533, and capacitor 529 stores the differential voltage between the voltage threshold of inverter 537 and the voltage threshold of inverter 535.

During a precharge phase, signal PH1 is asserted to close switch 507 to provide a path from ground (or other reference voltage) to capacitor 521 and to close switch 509 to provide a path from ground to capacitor 523. PH1A is asserted to close switch 511 to short the inverting input of amplifier 531 to its non-inverting output and to close switch 513 to short the non-inverting input of amplifier 531 to its inverting output. Signal PH1B is asserted to close switch 515 to short the inverting input of differential amplifier 533 to its single ended output. Signal PH1C is asserted to close switch 517 to short the input of inverter 535 to its output, and signal PH1D is asserted to close switch 519 to short the input of inverter 537 to its output. With the output of each amplifying device shorted to its input, the output and input of each device are at the voltage threshold of each device where differences in the voltage thresholds are stored in the intervening capacitors. During the precharge phase, switches 503 and 505 are open. In some embodiments, the precharge phase may be characterized as an autozeroing phase. In some embodiments, switches 507 and 509 may be connected to a reference voltage other than ground.

In the comparison phase, switches 507, 509, 511, 513, 515, 517, and 519 are opened which disables the shorting paths from the outputs to the inputs of the amplifying devices. The assertion of the PH2 signal closes switch 503 to provide a path from terminal VIN through capacitor 521 to the inverting input of amplifier 531 and closes switch 505 to provide a path from terminal VREF through capacitor 523 to the non-inverting input of amplifier 531. The voltages stored on capacitors 521 and 523 add to the voltages of these signals when being compared by differential amplifier 531.

During the comparison phase (Phase 2), the comparison of the voltages of VIN and VREF propagate through the series of stages. Differential amplifier 531 provides an initial determination of which voltage of VIN or VREF is higher based upon the voltages of its inputs. The voltage of VIN is level-shifted by the voltage stored on capacitor 521 before being provided to the inverting input of amplifier 531, and voltage of VREF is level-shifted by the voltage stored on capacitor 523 before being provided to the non-inverting input of amplifier 531. In the next stage, differential amplifier 533 provides an indication of which voltage is higher at its output based on the voltage differential of its inputs where the non-inverting output of amplifier 531 is level-shifted by the voltage stored on capacitor 525 and provided to the inverting input of amplifier 533 and the inverting output of amplifier 531 is provided to the non-inverting input of amplifier 533. The output of amplifier 533 is level-shifted by the voltage stored on capacitor 527 and provided to the input of inverter 535. The output of inverter 535 is level-shifted by the voltage stored on capacitor 529 and is provided to the input of inverter 537. The output of inventor 537 provides the COMPARE signal which indicates whether VIN or VREF is at a higher voltage. In the configuration shown, if VIN is at a higher voltage than VREF, the inverting output of amplifier 531 will be at a higher voltage than the noninverting output of amplifier 531, the output of amplifier 533 will be a high voltage, the output of inverter 535 will be at a low voltage, and the COMPARE signal will be at a high voltage.

During the propagation of the comparison of the voltages of VIN and VREF through the series of stages, the gain of the previous stages are multiplied by the gain of the next stage to provide an overall gain of the comparison. In one embodiment, the voltage differential of the outputs of a differential amplifier (531, 533) is the voltage differential of its inputs multiplied by the gain of the differential amplifier. Accordingly, with the configuration shown in FIG. 5, the effective gain of the comparison of VIN to VREF at the output of amplifier 533 is the gain of amplifier 531 times the gain of amplifier 533.

Because the initial comparisons of the voltage of VIN and VREF are made by differential amplifiers 531 and 533 and are based on the difference between voltages VIN and VREF and are not based on a voltage threshold of an inverter (which depends on its supply voltage) that was stored in a capacitor at a time when the supply voltage may be different than during the comparison phase, comparator 501 is more immune to issues due to power supply variation than comparator 113.

Furthermore, because the comparison determination at the output of amplifier 533 is provided at a higher gain (the gain of amplifier 531 times the gain of amplifier 533), the signal provided to inverter 535 is far less susceptible to power supply variations than if the inverter stage were the beginning stage of the series as with comparator 113. Accordingly, the relatively faster inverter stages can be used for later stages of the comparator for increasing the speed of the comparison operation.

In one embodiment, the gain of each of the four stages of comparator 501 is approximately 32X. Accordingly, the total gain of comparator 501 is approximately 1,000,000. However, comparators of other embodiments may have stages with different gains, or may have a different number of stages. For example, in one embodiment, a comparator may have only one inverter stage, or may have more than two inverter stages. Also, a comparator may have additional differential amplifier stages. Also, each of the stages may have a different gain from the other stages.

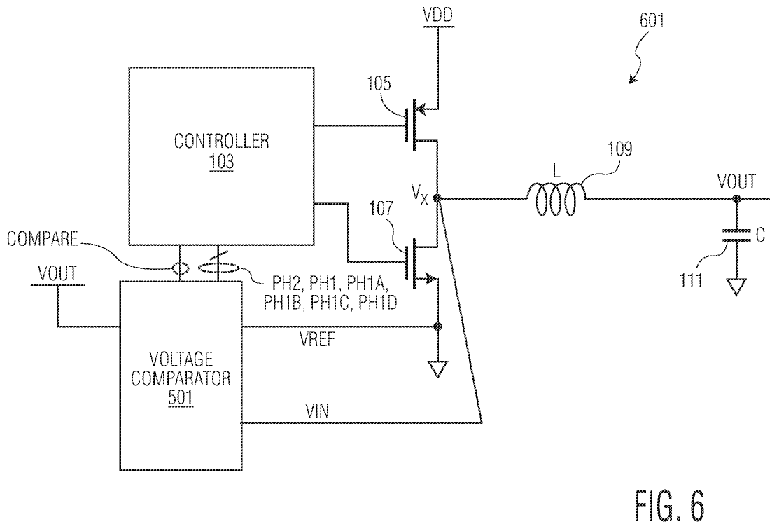

FIG. 6 is a switching power supply according to one embodiment of the present invention. Switching power supply 601 has a buck converter configuration and is similar to power supply 101 where items with same reference numbers are similar.

Power supply 601 differs from power supply 101 in that it utilizes voltage comparator 501 for determining when the current through inductor 109 is approximately 0 amps by comparing when the voltage of node VX exceeds ground during the inductor discharge phase of power supply 601. In the embodiment shown, comparator 501 provides the indication as the COMPARE signal to controller 103. In response to the COMPARE signal indicating that VX exceeds VREF, controller 103 turns off switch 107. In the embodiment shown, controller 103 also provides signals PH1, PH1A, PH1B, PH1C, PH1D, and PH2 for controlling the phases of comparator 501. However, these signals may be generated by other circuits in other embodiments.

In other embodiments, switching power supply 601 may utilize other comparators similar to comparator 501 in performing its operations. For example, a comparator similar to comparator 501 may be used to determine an overvoltage, undervoltage, over current, or under current condition to stop operations of the switching power supply or be utilized for hysteretic control of the output of a DC-DC convertor. Also in other embodiments, switching power supply 601 may have other configurations such as a boost configuration. Also, power supply 601 may be an AC to DC convertor in some embodiments. In other embodiments, comparator 501 may compare node VX to a different voltage other than ground (e.g. 0.1V or a supply voltage).

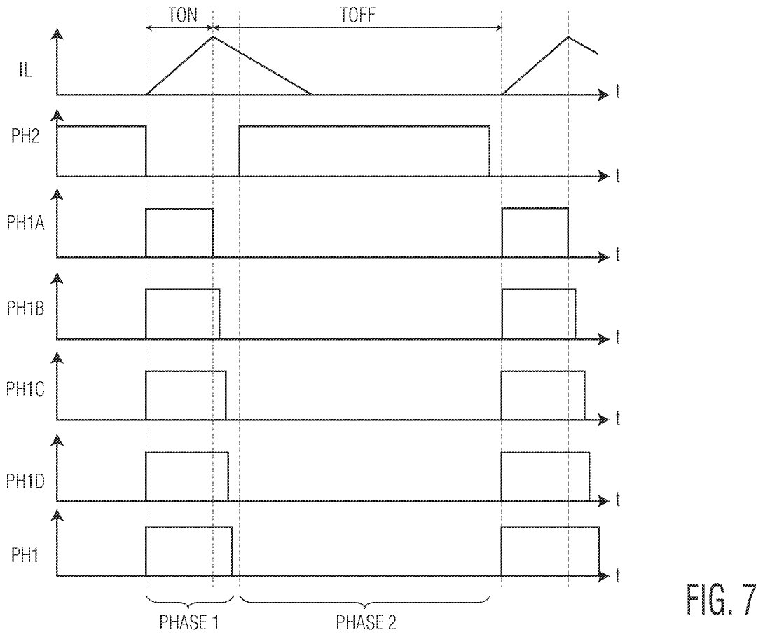

FIG. 7 is a timing diagram of power supply 601 that shows the phase control signals (PH1, PH1A, PH1B, PH1C, and PH2) that are applied to comparator 501 to control the timing of the precharge phase (Phase 1) and the comparison phase (Phase 2). As shown in FIG. 7, TON is the time when switch 105 is conducting and TOFF is the time when switch 105 is non conducting. As shown in FIG. 7, Phase 1 of comparator 501 (the precharge phase) occurs when the PHASE 1 signal is high. Phase 2 of comparator 501 (the comparison phase) occurs when the PHASE 2 signal is high. In the embodiment of FIG. 7, signals PH1A, PH1B, PH1C, and PH1D which are asserted during Phase 1, are de-asserted in a staggered manner where PH1A is de-asserted before PH1B, PH1B is de-asserted before PH1C, and PH1C is de-asserted before PH1D, and PH1D is de-asserted before PH1. The staggered de-assertion of the shorting path control signals reduces the inaccuracy introduced by charge injection that occurs from the opening of the switches of the shorting paths. In other embodiments, the Phase 1 and Phase 2 signals may be asserted in a different manner.

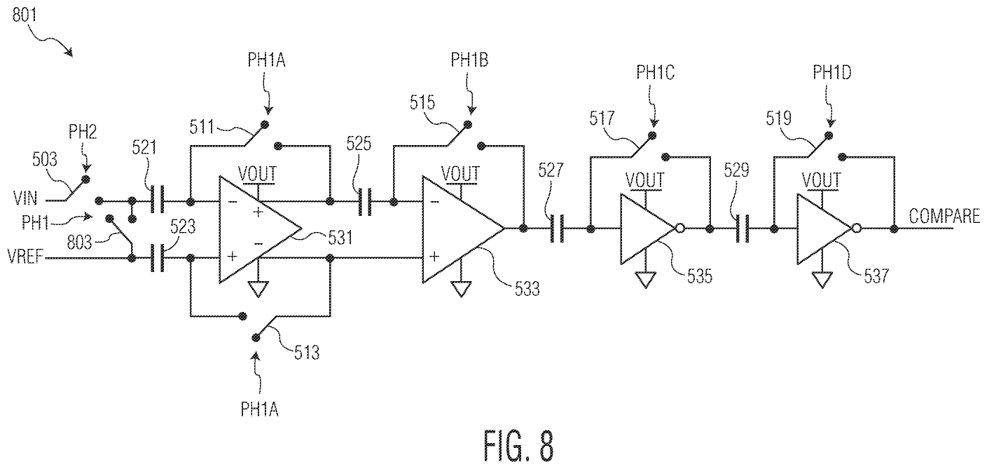

FIG. 8 is a circuit diagram of another embodiment of a comparator according to the present invention. The items having the same reference numbers as the items of FIG. 5 are similar.

Comparator 801 differs from comparator 501 of FIG. 5 in that capacitors 521 and 523 are charged to have the voltage differential between the voltage threshold of amplifier 531 and the voltage of the input terminal VREF during the precharge phase (Phase 1). An electrode of capacitor 523 is connected to input terminal VREF and an electrode of capacitor 521 is coupled to input terminal VREF via a switch 803 that is closed during Phase 1 and opened during Phase 2. During Phase 2 (the comparison phase) switch 803 is opened and switch 503 is closed to provide a path from input terminal VIN to the inverting input terminal of amplifier 531 via capacitor 521.

A comparator may have other devices, other configurations, and/or operate in other manners in other embodiments. For example, referring to FIG. 5, comparator 501 may include a capacitor located between the inverting output of amplifier 531 and the non-inverting input of amplifier 533. With such an embodiment, the comparator would also include a shorting path from the non-inverting input of amplifier 533 to a reference voltage. This shorting path would be conductive during the precharge phase of comparator 501. A comparator may include a different number of inverter stages (e.g., 1, or 3 or more inverters) in other embodiments. Also, a comparator may include additional differential amplifier stages after the second in series differential amplifier stages and before the inverter stages. Furthermore, in some embodiments, differential amplifier 531 may be configured to have a single ended output.

As described herein, implementing differential amplifiers for the first two stages in series of a multistage voltage comparator followed with one or more inverter stages in the series, may provide for a comparator that is relatively fast, has a high gain, has low-offset, and has a good power supply rejection ratio in that the differential amplifiers can be configured to provide a highly accurate voltage comparison under noisy supply wherein the faster inverter stages can be used as the later stages. Accordingly, the comparator has a relatively low propagation delay with a relatively high immunity to power supply voltage variation issues. Such a comparator may be highly beneficial for use in switching power supply applications where a voltage ripple may provide different voltage levels for the precharge phase and the comparison phase of the comparator. However, such a comparator may be used in other applications such as Class D audio amplifiers and voltage comparators for high resolutions, high speed analog to digital converters. Such a comparator maybe useful for applications that require relatively fast, low offset, high PSRR voltage comparators.

Implementing a comparator with differential amplifiers for at least the first two stages may provide for a comparator that utilizes differential comparisons for the lower gain comparisons in the earlier stages, thereby improving comparator accuracy of signals having a relatively small input voltage differential.

Features described herein with respect to one embodiment may be implemented in other embodiments described herein. A current electrode of a FET (field effect transistor) is a source or drain. A control electrode of a FET is a gate.

In one embodiment, a circuit includes a voltage comparator. The voltage comparator includes a first input terminal to receive a first voltage for comparison, a second input terminal to receive a second voltage for comparison, and a first stage. The first stage being a first in a series of stages. The first stage includes a first differential amplifier including a first input, a second input, and a first output. The first input is coupled to the first input terminal via at least a first capacitor. The second input is coupled to the second input terminal via at least a second capacitor. A first switch, that when closed shorts the first input to the first output. A second switch is coupled to an electrode of the second capacitor. The voltage comparator includes a second stage being the second in the series of stages. The second stage includes a second differential amplifier including a first input, a second input, and an output. The first input of the second differential amplifier is coupled to the first output of the first differential amplifier via at least a third capacitor. A third switch, that when closed shorts the first input of the second differential amplifier to the output of the second differential amplifier. The voltage comparator includes one or more inverter stages that are configured in a series as subsequent stages in the series of stages, wherein the one or more inverter stages includes a first inverter stage, the first inverter stage is a first in the series of the one or more inverter stages, an input of the first inverter stage is coupled to an output of a differential amplifier of an immediately previous stage in the series of stages by at least a fourth capacitor. The one or more inverter stages including an output to provide an indication of a comparison of a voltage of the first terminal input with a voltage of the second terminal input.

In another embodiment, a method in a circuit including a series of stages with the series of stages including a series of one or more inverter stages for providing an indication of a comparison between a voltage at a first node and a voltage at a second node at an output of the series of one or more inverter stages includes performing a precharge phase. The performing the precharge phase includes charging a first capacitor having first electrode in a path to a first input of a first differential amplifier of a first in series stage of the series of stages and a second electrode in a path to a reference voltage wherein the first input of the first differential amplifier is connected to a first output of the first differential amplifier with a first shorting path. The performing the precharge phase includes charging a second capacitor having first electrode in a path to a second input of the first differential amplifier and a second electrode in a path to the reference voltage wherein the second input of the first differential amplifier is connected to a second output of the first differential amplifier with a second shorting path. The performing the precharge phase includes charging a third capacitor having first electrode coupled to a first input of a second differential amplifier of a second in series stage of the series of stages and a second electrode coupled to the first output of the first differential amplifier wherein the first input of the second differential amplifier is connected to a first output of the second differential amplifier with a third shorting path. The performing a precharge phase includes charging a fourth capacitor having first electrode coupled to an input of an inverter of a first in series inverter stage of the series of one or more inverter stages and a second electrode coupled to an output of a differential amplifier of an immediately previous stage of the series of stages, wherein the input of the inverter is connected to an output of the inverter with a fourth shorting path. The method includes performing a comparison phase to obtain an indication of a comparison between the voltage at the first node and the voltage at the second node at the output of the series of one or more inverter stages. The performing the comparison phase includes making nonconductive the first shorting path, the second shorting path, the third shorting path, and the fourth shorting path and providing a path from a second electrode of the first capacitor to the first node and providing a path from second electrode of the second capacitor to the second node.

While particular embodiments of the present invention have been shown and described, it will be recognized to those skilled in the art that, based upon the teachings herein, further changes and modifications may be made without departing from this invention and its broader aspects, and thus, the appended claims are to encompass within their scope all such changes and modifications as are within the true spirit and scope of this invention.

1. A circuit comprising:
a voltage comparator comprising:
a first input terminal to receive a first voltage for comparison;
a second input terminal to receive a second voltage for comparison;
a first stage, the first stage being a first in a series of stages, the first stage comprising:
a first differential amplifier including a first input, a second input, and a first output;
wherein the first input is coupled to the first input terminal via at least a first capacitor;
wherein the second input is coupled to the second input terminal via at least a second capacitor;
a first switch, that when closed shorts the first input to the first output;
a second switch coupled to an electrode of the second capacitor;
a second stage, the second stage being the second in the series of stages, the second stage comprising:
a second differential amplifier including a first input, a second input, and an output;
wherein the first input of the second differential amplifier is coupled to the first output of the first differential amplifier via at least a third capacitor;
a third switch, that when closed shorts the first input of the second differential amplifier to the output of the second differential amplifier;
one or more inverter stages that are configured in a series as subsequent stages in the series of stages, wherein the one or more inverter stages includes a first inverter stage, the first inverter stage is a first in the series of the one or more inverter stages, an input of the first inverter stage is coupled to an output of a differential amplifier of an immediately previous stage in the series of stages by at least a fourth capacitor, the one or more inverter stages including an output to provide an indication of a comparison of a voltage of the first terminal input with a voltage of the second terminal input;
wherein the first input of the first differential amplifier is coupled to the first input terminal via at least the first capacitor and a fourth switch, the fourth switch is closed during a comparison phase to provide a path from the first input terminal to an electrode of the first capacitor.

2. The circuit of claim 1 wherein during a comparison operation of the voltage of the first input terminal to the voltage of the second input terminal, the voltage comparator operates in a precharge phase where the first switch, the second switch, and the third switch are closed to charge the first capacitor, the second capacitor, the third capacitor, and the fourth capacitor followed by the comparison phase where the first switch, the second switch, and the third switch are open.

3. The circuit of claim 2 wherein:
the input of the first inverter stage is coupled to the output of the second differential amplifier by at least the fourth capacitor;
the first differential amplifier includes a second output, the first output of the first differential amplifier and the second output of the first differential amplifier are differential outputs;
the second switch, when closed, shorts the second input of the first differential amplifier to the second output of the first differential amplifier;
wherein during the precharge phase, the first capacitor and the second capacitor are charged to a voltage that is dependent upon a voltage threshold of the first differential amplifier, the third capacitor is charged to a voltage that is dependent on the voltage threshold of first differential amplifier and a voltage threshold of the second differential amplifier, and the fourth capacitor is charged to a voltage that is dependent upon a voltage threshold of the first inverter stage and the voltage threshold second differential amplifier.

4. The circuit of claim 2 wherein during the precharge phase, the first capacitor and the second capacitor are charged to a voltage that is dependent upon a difference between the volage threshold of the first differential amplifier and a reference voltage.

5. The circuit of claim 4 wherein the reference voltage is the voltage of the second input terminal.

6. The circuit of claim 4 wherein the reference voltage is a separate voltage from the voltage of the first input terminal and the second input terminal.

7. The circuit of claim 2 wherein during the comparison phase, a voltage comparison of the voltage at the first input terminal and the second input terminal prorogates through the first differential amplifier, the second differential amplifier, and the series of the inverter stages of the one or more inverter stages to the output of the one or more inverter stages.

8. The circuit of claim 2 wherein during the precharge stage, the first and second switches are opened before the third switch.

9. The circuit of claim 2 wherein the fourth switch is open during the precharge phase.

10. (canceled)

11. The circuit of claim 1 further comprising a fifth switch, wherein the fifth switch is closed during a precharge phase for providing a reference voltage to the first capacitor, wherein the first input of the first differential amplifier is coupled to the fifth switch at least via the first capacitor, wherein the fifth switch is open during the comparison phase.

12. The circuit of claim 1 wherein the second input of the first differential amplifier is coupled to the second input terminal via at least the second capacitor and a fifth switch.

13. The circuit of claim 12 wherein during a comparison operation of the voltage of the first input terminal to the voltage of the second input terminal, the voltage comparator operates in a pre-charge phase where the first switch, the second switch, and the third switch, are closed to charge the first capacitor, the second capacitor, the third capacitor and the fourth capacitor, followed by the comparison phase where the first switch, the second switch, and the third switch are open and the fourth switch and the fifth switch are closed.

14. The circuit of claim 1 further comprising:
a switching power supply, wherein the first input terminal is configured to provide a voltage of a first node of the switching power supply and the second input terminal is configured to provide a voltage of a second node of the switching power supply.

15. The circuit of claim 14 wherein:
the switching power supply includes an output for providing a regulated voltage, wherein the first differential amplifier, the second differential amplifier, and inverters of the one or more inverter stages each include a supply rail that receives power from the output of the switching power supply.

16. The circuit of claim 1 further comprising:
a switching power supply, including an inductor;
wherein the first input terminal is configured to provide an indication of when of a current passing through the inductor is at a particular value.

17. The circuit of claim 1 wherein:
the first differential amplifier includes a second output, the first output of the first differential amplifier and the second output of the first differential amplifier are differential outputs;
the second input of the second differential amplifier is coupled to the second output of the first differential amplifier;
the second switch when closed shorts the second input of the first differential amplifier to the second output of the first differential amplifier.

18. A method comprising:
in a circuit including a series of stages with the series of stages including a series of one or more inverter stages for providing an indication of a comparison between a voltage at a first node and a voltage at a second node at an output of the series of one or more inverter stages, performing a precharge phase, wherein the performing a precharge phase includes:
charging a first capacitor having first electrode in a path to a first input of a first differential amplifier of a first in series stage of the series of stages and a second electrode in a path to a reference voltage wherein the first input of the first differential amplifier is connected to a first output of the first differential amplifier with a first shorting path;
charging a second capacitor having first electrode in a path to a second input of the first differential amplifier and a second electrode in a path to the reference voltage wherein the second input of the first differential amplifier is connected to a second output of the first differential amplifier with a second shorting path;
charging a third capacitor having first electrode coupled to a first input of a second differential amplifier of a second in series stage of the series of stages and a second electrode coupled to the first output of the first differential amplifier wherein the first input of the second differential amplifier is connected to a first output of the second differential amplifier with a third shorting path;
charging a fourth capacitor having first electrode coupled to an input of an inverter of a first in series inverter stage of the series of one or more inverter stages and a second electrode coupled to an output of a differential amplifier of an immediately previous stage of the series of stages, wherein the input of the inverter is connected to an output of the inverter with a fourth shorting path;
performing a comparison phase to obtain an indication of a comparison between the voltage at the first node and the voltage at the second node at the output of the series of one or more inverter stages, the performing the comparison phase includes:
making nonconductive the first shorting path, the second shorting path, the third shorting path, and the fourth shorting path;
providing a path from a second electrode of the first capacitor to the first node via a closed switch and providing a path from second electrode of the second capacitor to the second node.

19. The method of claim 18 wherein the reference voltage is a voltage at one of the first node or the voltage of the second node.

20. The method of claim 18 wherein the voltage at the first node is indicative of current through an inductor of a switching power supply, the indication of a comparison is used in detecting that current through the inductor has reach a particular value.
